(19) United States
(12) Patent Application Publication
(10) Pub. No.: US 2005/0073805 A1
(43) Pub. Date: Apr. 7, 2005

(54) Integrated circuit package

(76) Inventors: Brent Stone, Chandler, AZ (US); Kenneth Kassa, Queen Creek, AZ (US); Brian DeFord, Chandler, AZ (US); Erik Peter, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/666,462

(22) Filed: Sep. 19, 2003

(51) Int. Cl. H05K 7/00

(52) U.S. Cl. 361/679

(57) ABSTRACT

According to one embodiment, an apparatus is disclosed. The apparatus includes a printed circuit board (PCB), a connector mounted on the PCB, and an integrated circuit (IC) package for insertion into the connector. The IC package includes a plurality of lands having a varied pitch distance.

### FIELD OF THE INVENTION

The present invention relates to integrated circuits; more particularly, the present invention relates to integrated circuit packages.

### BACKGROUND

With the continued advancement of computer systems there is a desire to increase input/output (I/O) and power delivery interconnect performance, resulting in higher pin (or land) counts of socketed integrated circuit devices. Increasing the land (or pin) count of an integrated circuit typically results in increased package and socket size as the land pitch, the center to center spacing between lands, is uniform. An alternative method is to uniformly reduce the land pitch to minimize the impact of increasing the physical size of a device.

For a given socket technology, there is also a practical high volume manufacturing (HVM) limit restricting the extent to which socket land pitch can be reduced. At this time something larger than 1 mm in any dimension represents a HVM limit for various types of sockets (e.g., stamped metal contact land grid array (LGA) sockets). Therefore, if a target land count cannot be reached given a desired body size and the minimum HVM pitch limit, the only way to increase land count is to grow body size over the target. Growth to package body size represents significant cost because all components of the total integrated circuit solution increase in cost. Another limitation for increasing land count by reducing pitch is motherboard routing technologies used in breaking out signals from the socket. At this time, it is generally agreed that a 5 mil line width and 5 mil line-2-line space paired with a 25 mil pad via and an 18 mil socket pad represent the industry standard technology base for motherboard routing rules. The combination of these technologies with the desired signal to ground ratio for a device will limit how many rows deep land side motherboard breakout can reach. Non-land side breakout on the motherboard is limited by line geometries, via pad size, and via pitch.

### BRIEF DESCRIPTION OF THE DRAWINGS

The present invention will be understood more fully from the detailed description given below and from the accompanying drawings of various embodiments of the invention. The drawings, however, should not be taken to limit the invention to the specific embodiments, but are for explanation and understanding only.

FIG. 1 illustrates one embodiment of a motherboard, integrated circuit (IC) package and IC socket;

FIG. 2 illustrates one embodiment of a motherboard, IC package with an unmated IC;

FIG. 3 illustrates one embodiment of a motherboard, IC package with an IC package inserted into an IC socket;

FIG. 4 illustrates one embodiment of a motherboard, IC package with a retention mechanism compressing the IC package into an IC socket;

FIG. 5 illustrates a bottom view of one embodiment of an IC package with fixed (or uniform) pitch interconnect;

FIG. 6 illustrates one embodiment of pitch definitions for motherboard technology baselines;

FIG. 7 illustrates another embodiment of pitch definitions for motherboard technology baselines;

FIG. 8 illustrates yet another embodiment of pitch definitions for motherboard technology baselines;

FIG. 9 illustrates one embodiment of a motherboard breakout;

FIG. 10 illustrates a partial top view of one embodiment of mixed row and columnar pitch stamped contact IC socket;

FIG. 11 illustrates one embodiment of motherboard footprint with uniform, mixed pitch;

FIG. 12 illustrates a top view of one embodiment of motherboard breakout for a uniform, mixed pitch IC socket;

FIG. 13 illustrates a bottom view of one embodiment of motherboard breakout for a uniform, mixed pitch IC socket;

FIG. 14(A) illustrates a bottom view of one embodiment of a IC package with mixed pitch interconnect; and

FIG. 14(B) illustrates an isometric view of one embodiment of an IC socket with mixed pitch.

### DETAILED DESCRIPTION

An integrated circuit (IC) package with mixed pitch is described. In the following description, numerous details are set forth. It will be apparent, however, to one skilled in the art, that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

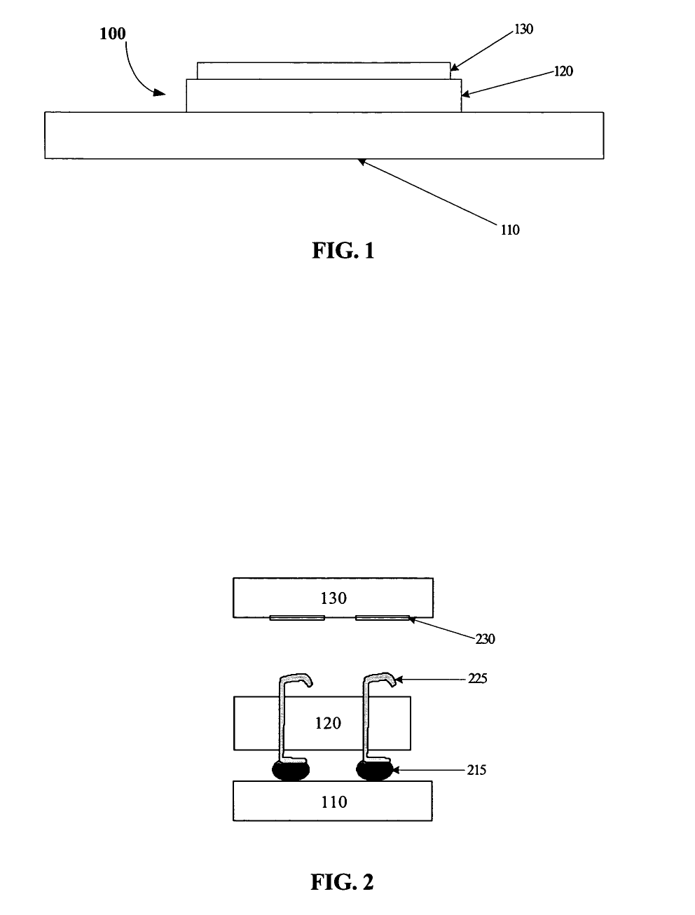

FIG. 1 illustrates one embodiment of a system 100. System 100 includes an IC package 130 mounted in a socket 120 on motherboard 110. Motherboard 110 is a physical arrangement in a computer system that includes the computer system's basic circuitry and components. On motherboard 110, circuitry is imprinted or affixed to the surface of a firm planar surface.

Socket 120 facilitates an electrical connection between IC 130 and circuits on motherboard 110. IC 130 is a semiconductor wafer on which thousands or millions of tiny resistors, capacitors, and transistors are fabricated. According to one embodiment, socket 120 is a zero insertion force (ZIF) connector. However, in other embodiments, socket 120 may be implemented using other types of sockets (e.g., PGA). According to one embodiment, IC package 130 is a land grid array (LGA), with an accompanying LGA socket 120. However, in other embodiments, IC 130 may function as a pin grid array (PGA) or other type of microprocessor or IC circuitry with the accompanying PGA socket 120.

FIG. 2 illustrates one embodiment of motherboard 110, LGA IC socket 120 with an unmated LGA IC 130. Motherboard 110 is coupled to solder balls 215. Solder balls 215 are coupled to land pads on motherboard 110 (not shown) to facilitate electrical contact at motherboard 110 for transmitting and receiving electrical signals.

Contacts 225 are mounted on solder balls 215 as a component of socket 120 to provide a connection between motherboard 110 and IC package 130. In one embodiment, contacts 225 are stamped metal contacts. Lands 230 are mounted on package 130 to provide an electrical contact at package 130 for transmitting and receiving electrical signals.

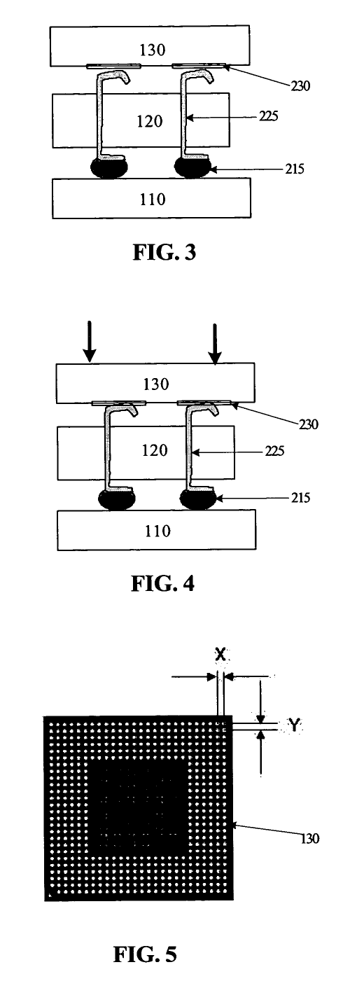

FIG. 3 illustrates one embodiment of IC package 130 manually inserted onto motherboard 110 via IC socket 120. In this embodiment, lands 230 physically connect with contacts 225, thus providing an electrical path between motherboard 110 and package 130.

FIG. 4 illustrates one embodiment of IC package 130 manually inserted into IC socket 120 via a sustained compressive load. In such an embodiment, a loading mechanism (not depicted) compresses package 130 into socket 120.

FIG. 5 illustrates a bottom view of one embodiment of an IC package 130. As shown in FIG. 5, the lands on IC package 130 have a fixed distance (or pitch) between any two land centers in both the X and Y directions. As discussed above, there is a desire to increase I/O and power delivery interconnect performance through increased pin count.

However as described above, traditional socketed IC packages utilize a uniform (fixed) pitch that is maintained throughout the pinfield. Increasing pin counts with IC packages have been offset with scaling a fixed pitch to lower levels. Nonetheless, the cost of reducing pitch is becoming a significant challenge with fine pitched (<1.27 mil) interconnects on large, low layer count printed circuit boards due to routing challenges.

Moreover, there are manufacturing and design constraints with a given socket technology that affect the pitch. Maintaining consistent row and/or column symmetry is desirable for manufacturing of stamped metal contact technologies. For stamped metal LGA contacts, a design constraint is introduced where the required contact deflection to mate with the IC package may limit the minimum pitch reduction in one direction “X” by a different amount than more than a perpendicular direction “Y”

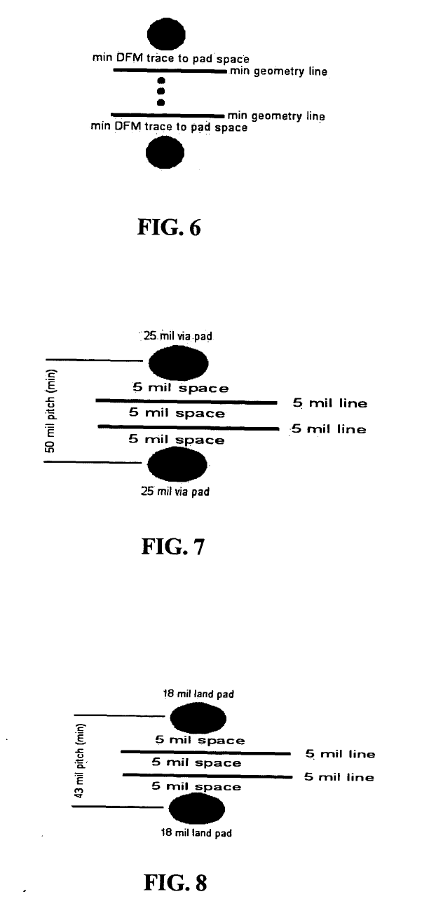

FIG. 6 illustrates one embodiment of pitch definitions for motherboard technology baselines. Referring to FIG. 6, IC land pads are separated by a fixed distance, with a minimum distance between the land pads and the nearest trace. In addition, a minimum distance is maintained between each trace. Typically the distance between a land pad and a trace, and between traces, is 5 mil.

FIG. 7 illustrates another embodiment of pitch definitions for motherboard technology baselines. In FIG. 7, 25 mil land pads are shown, having a pitch of 50 mil. In between are 5 mil traces spaced at 5 mils apart. FIG. 8 illustrates yet another embodiment of pitch definitions for motherboard technology baselines. In FIG. 8, 18 mil land pads are shown, having a pitch of 43 mil, with 5 mil traces spaced at 5 mils apart.

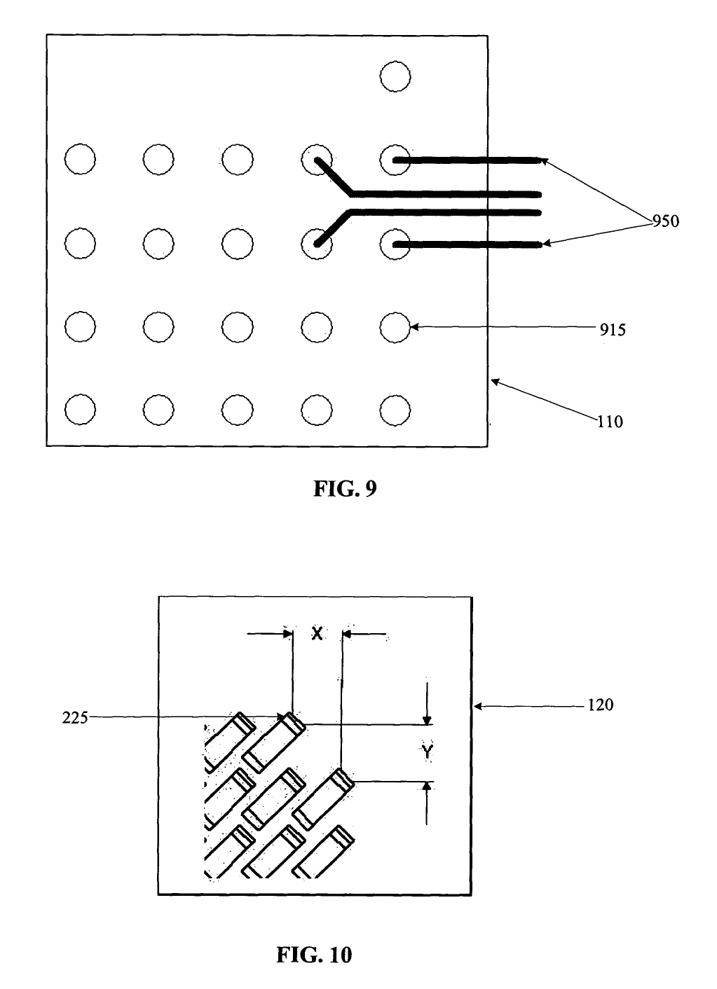

FIGS. 7 and 8 show that the pitch between land pads may be reduced without sacrificing the minimum distance between land pads and traces. Thus, additional land pads may be placed on an IC. FIG. 9 illustrates one embodiment of a motherboard 110 breakout. Motherboard 110 includes land pads 915, with traces 950 coupled to pads 915 for signal routing. As described above, the breakout is limited by line geometries, via pad size, and pitch.

According to one embodiment, motherboard 110, socket 120 and IC package 130 have a different pitches between various land pads, contacts and lands, respectively, to facilitate an optimal balance for increasing contact density with maintained socket manufacturability and accommodating lower cost motherboard 110 designs.

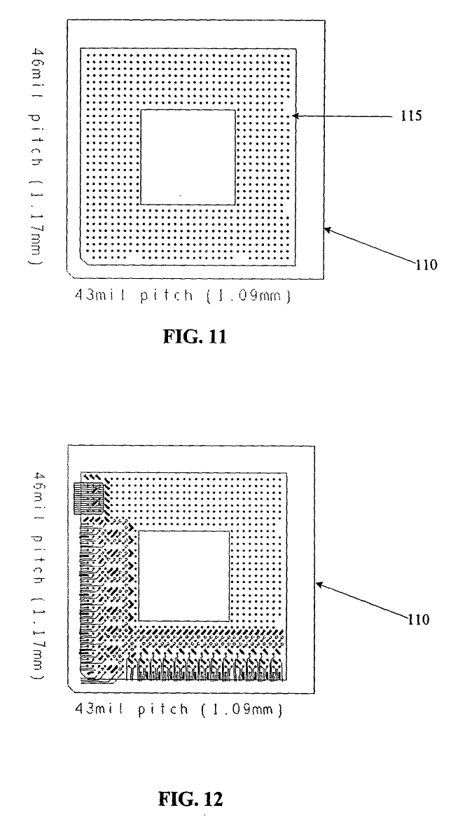

FIG. 10 illustrates a partial top view of one embodiment of socket 120 having mixed row and columnar contacts 225. As shown in FIG. 10, the vertical (X) and horizontal (Y) distances between contacts 225 are varied. FIG. 11 illustrates one embodiment of motherboard 110 footprint with uniform, mixed pitch. In one embodiment, the vertical pitch between land pads is 46 mil, while the horizontal distance is 43 mil.

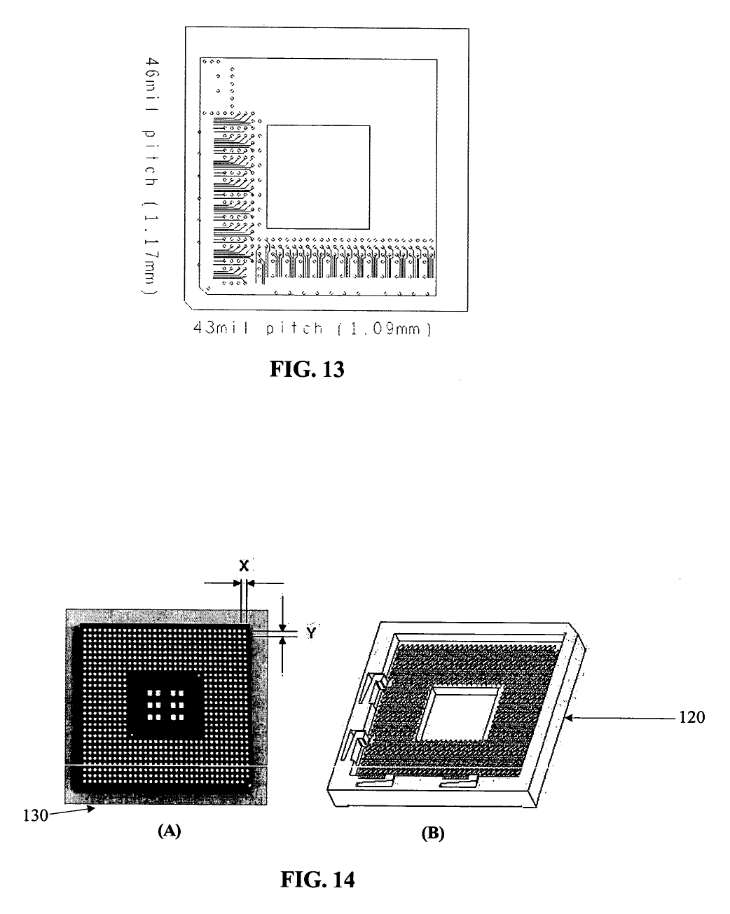

FIG. 12 illustrates a top view of one embodiment of motherboard 110 breakout, on the land side of motherboard 110. FIG. 12 shows the routing of traces 950 to land pads 915 on motherboard 110. FIG. 13 illustrates a bottom view of one embodiment of motherboard 110 breakout on the non-land side of motherboard 110. FIG. 14(A) illustrates a bottom view of one embodiment of a land grid array IC package with mixed pitch interconnect. FIG. 14(B) illustrates an isometric view of one embodiment of a land grid array IC socket using stamped metal contacts with mixed pitch.

The mixed pitch between lands on an IC package increases contact density without requiring improved motherboard routing and socket manufacturing capabilities. The resulting increase in contact density allows for a smaller package, smaller socket, and a corresponding reduction in motherboard real estate, enabling for cost optimized components to be created without sacrificing performance.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as the invention.

1. An apparatus comprising:
a printed circuit board (PCB);
a connector mounted on the PCB; and
an integrated circuit (IC) package for insertion into the connector, the IC package having a plurality of lands with a varied pitch distance.

2. The apparatus of claim 1 wherein the plurality of lands include a vertical pitch having a first distance and a horizontal pitch having a second distance.

3. The apparatus of claim 1 wherein the connector includes a plurality of contacts having a varied pitch distance to match the plurality of lands.

4. The apparatus of claim 3 wherein the PCB comprises a plurality of land pads having a varied pitch distance to match the plurality of contacts.

5. The apparatus of claim 4 wherein the PCB comprises a plurality of traces coupled to the plurality of land pads.

6. The apparatus of claim 1 wherein the PCB is a motherboard.

7. The apparatus of claim 1 wherein the connector is a zero insertion force (ZIF) connector.

8. The apparatus of claim 1 wherein the IC package is a land grid array (LGA).

9. An apparatus comprising:
a printed circuit board (PCB);
a connector mounted on the PCB; and
an integrated circuit (IC) package for insertion into the connector, the IC package having a plurality of pins with a varied pitch distance.

10. The apparatus of claim 9 wherein the plurality of pins include a vertical pitch having a first distance and a horizontal pitch having a second distance.

11. The apparatus of claim 10 wherein the PCB comprises a plurality of pin pads having a varied pitch distance to match the plurality of pins.

12. The apparatus of claim 9 wherein the IC package is a pin grid array (PGA).

13. An integrated circuit (IC) comprising:
one or more logic elements; and
a plurality of input/output pins (I/O) connectors, coupled to the one or more logic elements, having a varied pitch distance.

14. The IC of claim 13 wherein the plurality of I/O connectors include a vertical pitch having a first distance and a horizontal pitch having a second distance.

15. The IC of claim 13 wherein the plurality of I/O connectors comprise lands.

16. The IC of claim 13 wherein the plurality of I/O connectors comprise pins.
